(19) United States
(12) Patent Application Publication
(10) Pub. No.: US 2009/0061538 A1
(43) Pub. Date: Mar. 5, 2009

(54) Methods of forming ferroelectric capacitors and methods of manufacturing semiconductor devices using the same

(75) Inventors: Jang-Eun Heo, Seoul (KR); Choong-Man Lee, Seoul (KR); Ik-Soo Kim, Yongin-si (KR); Dong-Hyun Im, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/222,700

(22) Filed: Aug. 14, 2008

(30) Foreign Application Priority Data
Aug. 16, 2007 (KR) 10-2007-0082151

(51) Int. Cl. H01L 21/02

(52) U.S. Cl. 438/3; 257/E21.011

(57) ABSTRACT

In a method of forming a ferroelectric capacitor, a lower electrode layer is formed on a substrate. A first crystalline layer is formed on the lower electrode layer. A ferroelectric layer is formed on the first crystalline layer. The first crystalline layer one of prevents a component of the ferroelectric layer from diffusing into the lower electrode layer and mitigates fatigue of the ferroelectric layer. An upper electrode layer is formed on the ferroelectric layer.

### PRIORITY STATEMENT

This application claims priority under 35 USC § 119 to Korean Patent Application No. 2007-82151, filed on Aug. 16, 2007 in the Korean Intellectual Property Office (KIPO), the entire contents of which is incorporated herein by reference.

### BACKGROUND

### Description of the Related Art

A ferroelectric material including titanium and oxygen is used in conventional ferroelectric random access memory (FRAM) devices. This conventional ferroelectric material may be, for example, lead zirconate titanate [Pb(Zr, Ti)O₃; PZT], strontium bismuth tantalate (SrBi₂Ta₂O₉; SBT), bismuth lanthanum titanate [(Bi, La)TiO₃; BLT], lead lanthanum zirconate titanate [(Pb, La)(Zr, Ti)O₃; PLZT] or barium strontium titanate [(Ba, Sr)TiO₃; BST]. Among the above materials, PZT has been more widely used because PZT has a relatively high remaining polarization and a PZT layer may be formed at a relatively low temperature.

However, a PZT layer may be fatigued during repeated polarization reversal. Additionally, as integration of FRAM devices increase, lead in the PZT layer may diffuse into an insulation layer formed under a lower electrode. The lead reacts with the insulation layer, thereby generating defects therein. Example defects are shown in FIG. 1. Furthermore, oxygen used in forming the PZT layer may diffuse into a plug formed under the lower electrode. The oxygen reacts with the plug, thereby generating defects therein. Examples of these defects are shown in FIG. 2.

To suppress the above-discussed defects, a diffusion barrier layer may be formed between a ferroelectric layer and a lower electrode or an upper electrode, so that diffusion of components of the ferroelectric layer into other layers may be suppressed and/or prevented. In one example, the diffusion barrier layer may include strontium ruthenium oxide (SrRuO₃; SRO).

Conventionally, a crystalline strontium ruthenium oxide layer is formed by depositing materials in an amorphous state on the lower electrode and annealing the deposited materials. However, when the crystalline strontium ruthenium oxide layer is formed by depositing an amorphous state material and annealing, ruthenium tetraoxide (RuO₄) included in the strontium ruthenium oxide layer may be volatilized or ruthenium dioxide (RuO₂) in the strontium ruthenium oxide layer may be extracted. As a result, the crystalline strontium ruthenium oxide layer may have defects. Examples of these defects are shown in FIGS. 3 and 4, respectively.

When a ferroelectric layer is formed on a defective strontium ruthenium oxide layer, a leakage current may occur between the strontium ruthenium oxide layer and the ferroelectric layer. Example characteristics of leakage current in response to an applied voltage is shown in FIG. 5. Additionally, a conventional FRAM device including the above layers may have a relatively poor polarization-voltage (P-V) hysteresis loop. An example P-V hysteresis loop of respective locations (top portion: T, central portion: C, bottom portion: B, left portion: L, and right portion: R) of a substrate in response to an applied voltage is shown in FIG. 6. A conventional FRAM device having defects or relatively poor P-V hysteresis loop may have a relatively low reliability.

### SUMMARY

Example embodiments relate to methods of forming ferroelectric capacitors and methods of manufacturing semiconductor devices using the same. At least some example embodiments relate to methods of forming ferroelectric capacitors including a diffusion barrier layer and methods of manufacturing semiconductor devices using the same.

Example embodiments provide methods of forming ferroelectric capacitors including a diffusion barrier layer having reduced defects. Example embodiments also provide methods of manufacturing semiconductor devices including methods of forming ferroelectric capacitors including the diffusion barrier layer having reduced defects.

At least one example embodiment provides a method of forming a ferroelectric capacitor. According to at least this example embodiment, a lower electrode layer may be formed on a substrate. A first crystalline diffusion barrier layer may be formed on the lower electrode layer. A ferroelectric layer may be formed on the first crystalline diffusion barrier layer. The first crystalline diffusion barrier layer may suppress and/or prevent a component of the ferroelectric layer from diffusing into the lower electrode layer. An upper electrode layer may be formed on the ferroelectric layer.

According to at least some example embodiments, the first crystalline diffusion barrier layer may be formed without amorphous deposition and/or annealing. The first crystalline diffusion barrier layer may be formed using strontium ruthenium oxide (SrRuO₃; SRO). The first crystalline diffusion barrier layer may be formed at a temperature of between about 450° C. and about 550° C., inclusive, using a sputtering process. The sputtering process may be performed under a pressure of between about 5.8 mTorr and about 6.2 mTorr, inclusive, at a power of between about 200 W and about 700 W, inclusive. After the sputtering process is performed, a heat treatment process may be performed on the first crystalline diffusion barrier layer at a temperature of between about 450° C. and about 600° C., inclusive. The sputtering process may be performed using argon gas or a mixed gas including, for example, argon gas and oxygen gas.

According to example embodiments, the argon gas may be provided at a flow rate of between about 45 and about 85 sccm, inclusive. The oxygen gas may be provided at a flow rate of between about 10 and about 30 sccm, inclusive. Thus, a flow rate ratio between the argon gas and the oxygen gas may be in a range of between about 1.0:0.1 and about 1.0:0.7, inclusive. The argon gas may be further provided onto a rear surface of the substrate at a flow rate of about 15 sccm.

According to at least some example embodiments, the first crystalline diffusion barrier layer may be formed to have a thickness of between about 5, and about 45 A, inclusive. A second crystalline diffusion barrier layer may be formed on the ferroelectric layer. The second crystalline diffusion barrier layer may be formed at a temperature of between about 450° C. and about 550° C., inclusive, by a sputtering process. The ferroelectric layer may be formed using lead zirconate titanate [Pb(Zr, Ti)O₃; PZT], strontium bismuth tantalate (SrBi₂Ta₂O₉; SBT), bismuth lanthanum titanate [(Bi, La)TiO₃; BLT], lead lanthanum zirconate titanate [(Pb, La)(Zr, Ti)O₃; PLZT], barium strontium titanate [(Ba, Sr)TiO₃; BST], etc. The ferroelectric layer may be formed to have a thickness of between about 100 Å and about 800 Å, inclusive. The ferroelectric layer may include PZT having the formula of Pb(Zr₁₋ₓ, Tiₓ)O₃, wherein 0.65≦x≦0.80).

According to at least some example embodiments, the ferroelectric layer may be formed by a metal organic chemical vapor deposition (MOCVD) process, a chemical vapor deposition (CVD) process, an atomic layer deposition (ALD) process or the like. According to at least some example embodiments, the ferroelectric layer may be formed in a chamber of a MOCVD apparatus. The chamber may include a shower head for spraying a gas. The shower head may be a distance of about 10 mm from the substrate. The lower electrode layer may be formed using iridium, platinum, ruthenium, palladium, gold, iridium oxide, tin oxide, calcium ruthenium oxide (CaRuO₃; CRO), iridium ruthenium, or indium tin oxide (ITO). These may be used alone or in a combination thereof.

According to at least some example embodiments, the upper electrode layer may be formed using iridium, platinum, ruthenium, palladium, gold, iridium oxide, tin oxide, calcium ruthenium oxide (CRO), iridium ruthenium, or indium tin oxide (ITO). These may be used alone or in a combination thereof.

At least one other example embodiment provides a method of forming a ferroelectric capacitor. In at least this example embodiment, a lower electrode layer may be formed on a substrate. A first crystalline strontium ruthenium oxide (SRO) layer may be formed on the lower electrode layer. A ferroelectric layer may be formed on the first crystalline strontium ruthenium oxide layer. The first crystalline strontium ruthenium oxide layer may mitigate fatigue of the ferroelectric layer. A second crystalline strontium ruthenium oxide layer may be formed on the ferroelectric layer. An upper electrode layer may be formed on the second crystalline strontium ruthenium oxide layer.

According to at least some example embodiments, the first and second crystalline strontium ruthenium oxide layers may be formed at a temperature of between about 450° C. and about 550° C., inclusive, by a sputtering process.

At least one other example embodiment provides a method of manufacturing a semiconductor device. According to at least this example embodiment, a switching element may be formed on a substrate. A lower electrode layer electrically connected to the switching element may be formed. A first crystalline diffusion barrier layer may be formed on the lower electrode layer. A ferroelectric layer may be formed on the first crystalline diffusion barrier layer. The first crystalline diffusion barrier layer may suppress and/or prevent a component of the ferroelectric layer from diffusing into the lower electrode layer. An upper electrode layer may be formed on the ferroelectric layer.

According to at least some example embodiments, the first crystalline diffusion barrier layer may be formed using strontium ruthenium oxide (SRO). The first crystalline diffusion barrier layer may be formed at a temperature of between about 450° C. and about 550° C., inclusive, by a sputtering process. After the sputtering process is performed, a heat treatment process may be performed on the first crystalline diffusion barrier layer at a temperature of between about 450° C. and about 600° C., inclusive. The first crystalline diffusion barrier layer may be formed to have a thickness of between about 5 Å and about 45 Å, inclusive. A second crystalline diffusion barrier layer may be formed on the ferroelectric layer.

According to at least some example embodiments, the ferroelectric layer may be formed using lead zirconate titanate (PZT), strontium bismuth tantalate (SBT), bismuth lanthanum titanate (BLT), lead lanthanum zirconate titanate (PLZT) or barium strontium titanate (BST). These may be used alone or in a combination thereof.

According to at least one other example embodiment, a crystalline diffusion barrier layer may be formed beneath and on a ferroelectric layer so that components of the ferroelectric layer may be suppressed and/or prevented from diffusing into peripheral layers (e.g., a lower electrode layer, an upper electrode layer, a plug, etc.) and fatigue of the ferroelectric layer may be reduced. The crystalline diffusion barrier layer may be formed at a relatively high temperature by a sputtering process, and thus, defects generated during annealing an amorphous layer after depositing the amorphous layer at a relatively low temperature, may not be generated in the crystalline diffusion barrier layer. Thus, a ferroelectric capacitor including the diffusion layer may have improved (e.g., relatively good) P-V hysteresis characteristics and/or reduced leakage current characteristics. Additionally, a semiconductor device including the ferroelectric capacitor may have an enhanced reliability.

### BRIEF DESCRIPTION OF THE DRAWINGS

Example embodiments will be more clearly understood from the following detailed description taken in conjunction with the accompanying drawings. FIGS. 1 to 10D represent non-limiting, example embodiments as described herein.

FIG. 1 is a scanning electron microscope (SEM) picture illustrating defects due to the reaction between lead and silicon oxide in a conventional ferroelectric capacitor;

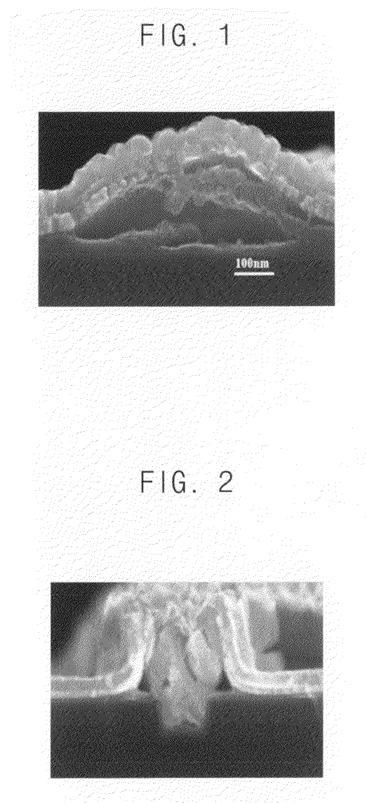

FIG. 2 a SEM picture illustrating defects due to the reaction between lead and a tungsten plug in a conventional ferroelectric capacitor;

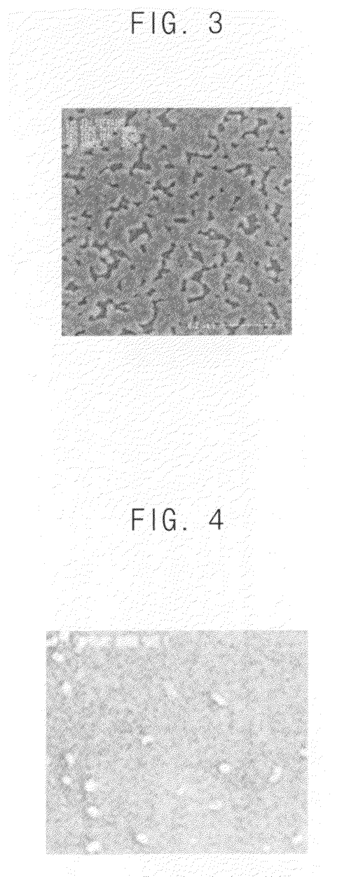

FIG. 3 is a SEM picture illustrating defects due to the volatilization of ruthenium tetraoxide (RuO₄) in a conventional SRO layer;

FIG. 4 is a SEM picture illustrating defects due to the extraction of ruthenium dioxide (RuO₂) in a conventional SRO layer;

FIG. 5 is a graph illustrating the leakage current characteristics of a conventional ferroelectric capacitor;

FIG. 6 is a P-V hysteresis loop of a conventional ferroelectric capacitor;

FIGS. 7 to 12 are cross-sectional views illustrating a method of forming a ferroelectric capacitor according to example embodiments;

FIG. 13 is a cross-sectional view illustrating a metal-organic chemical vapor deposition (MOCVD) apparatus for forming the ferroelectric layer according to example embodiments;

FIGS. 14A to 14C are graphs illustrating the relationships between the thickness of the SRO layer and the leakage current in accordance with example embodiments, which are graphs at locations (top portion: T, central portion: C, bottom portion: B, left portion: L, and right portion: R) of the substrate 100 when the thicknesses of the SRO layer are about 10 Å, 20 Å and 50 Å, respectively;

FIG. 15 is a graph illustrating a polarization ratio of the ferroelectric capacitor in accordance with example embodiments with respect to time;

FIG. 16 is a scanning electron microscope (SEM) picture of a crystalline SRO layer included in the ferroelectric capacitor according to example embodiments;

FIG. 17 is a P-V hysteresis loop of the ferroelectric capacitor according to example embodiments;

FIG. 18 is a graph illustrating a leakage current of the ferroelectric capacitor according to example embodiments; and

FIGS. 19 to 23 are cross-sectional views illustrating a method of manufacturing a semiconductor device using the method of forming the ferroelectric capacitor in accordance with example embodiments.

### DETAILED DESCRIPTION OF EXAMPLE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

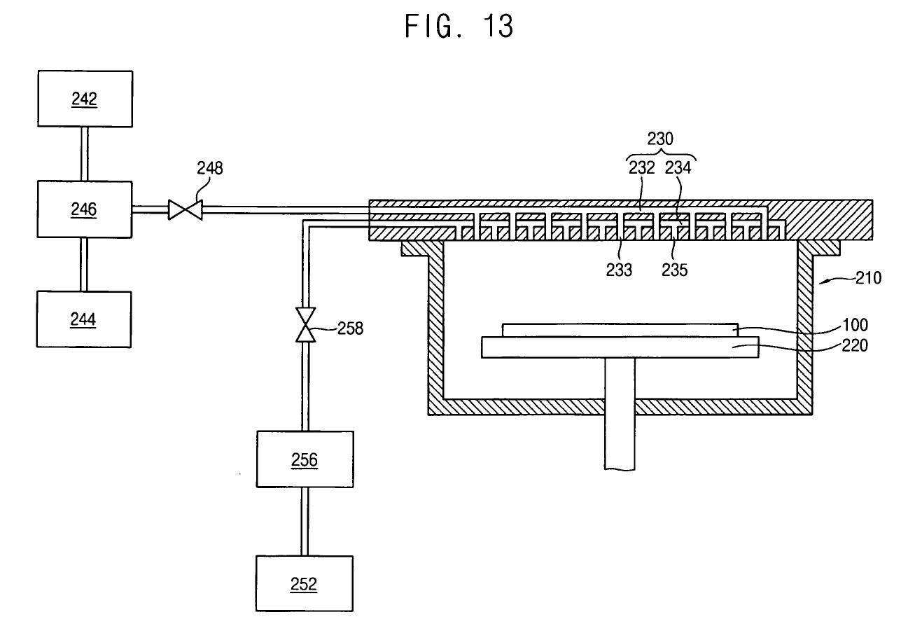

FIGS. 7 to 12 are cross-sectional views illustrating a method of forming a ferroelectric capacitor in accordance with example embodiments.

Referring to FIG. 7, a lower structure 105 may be formed on or within a substrate 100. The substrate 100 may include a semiconductor substrate, a metal oxide substrate or the like. For example, the substrate 100 may be a silicon wafer, a silicon-on-insulator (SOI) substrate, an aluminum oxide single crystalline substrate, a strontium titanium oxide single crystalline substrate, a magnesium oxide single crystalline substrate, or the like.

The lower structure 105 may be a contact area, a conductive wiring, a conductive pattern, a pad, a plug, a contact, a gate structure, a transistor, or similar structure.

An insulating structure 110 may be formed on the substrate 100 to cover the lower structure 105. The insulating structure 110 may include at least one insulation layer or insulating interlayer formed by a chemical vapor deposition (CVD) process, a plasma enhanced chemical vapor deposition (PECVD) process, a high density plasma chemical vapor deposition (HDP-CVD) process, an atomic layer deposition (ALD) process, etc. The insulating structure 110 may include at least one insulating layer or insulating interlayer including an oxide such as boro-phosphor silicate glass (BPSG), phosphor silicate glass (PSG), undoped silicate glass (USG), spin on glass (SOG), flowable oxide (FOX), plasma enhanced tetraethylorthosilicate (PE-TEOS), high density plasma chemical vapor deposition (HDP-CVD) oxide, or the like; or a nitride.

The insulating structure 110 may be at least partially removed to form a hole (not illustrated) exposing the lower structure 105 through the insulating structure 110. In at least one example embodiment, after forming a first photoresist pattern (not illustrated) on the insulating structure 110, the insulating structure 110 may be patterned using the first photoresist pattern as an etching mask, thereby forming the hole exposing the lower structure 105. The first photoresist pattern may be removed by an ashing process, a stripping process or the like. According to at least one other example embodiment, an anti-reflective layer (ARL) may be formed between the insulating structure 110 and the first photoresist pattern before forming the hole through the insulating structure.

A first conductive layer and a second conductive layer may be formed on the insulating structure 110 to fill the hole. Upper portions of the first and second conductive layers may be removed to expose at least an upper surface of the insulating structure, thereby forming a plug 120 filling the hole. The plug 120 may include a first conductive pattern 122 and a second conductive pattern 124. The second conductive layer may be formed using doped polysilicon or a metal such as tungsten, aluminum, titanium, copper, or the like. The first conductive layer may be formed using a conductive metal nitride such as tungsten nitride, aluminum nitride, titanium nitride, or the like. The first conductive pattern 122 may suppress and/or prevent components of the second conductive pattern 124 from diffusing into the insulating structure 110 and/or the lower structure 105. The first and second conductive layers may be formed using a sputtering process, a CVD process, an ALD process, or a pulse laser deposition (PLD) process. The plug 120 may be formed by removing the upper portions of the first and second conductive layers through a chemical mechanical polishing (CMP) and/or an etch-back process. The plug 120 may electrically connect an adhesion layer 130 (see FIG. 8) and a lower electrode layer 140 (see FIG. 8) to the lower structure 105.

Referring to FIG. 8, the adhesion layer 130 may be formed on the insulating structure 110 and the plug 120 to enhance the adhesive strength between the insulating structure 110 and the lower electrode layer 140. The adhesion layer 130 may be formed using a metal or a conductive metal nitride. For example, the adhesion layer 130 may be formed using titanium, tantalum, aluminum, tungsten, titanium nitride, tantalum nitride, aluminum nitride, tungsten nitride, titanium aluminum nitride, or the like. The adhesion layer 130 may be formed by a sputtering process, a CVD process, an ALD process, or a PLD process. According to at least one example embodiment, the adhesion layer 130 may be formed to have a thickness of about 50 Å.

The lower electrode layer 140 may be formed on the adhesion layer 130. The lower electrode layer 140 may be formed using a metal or a metal oxide. For example, the lower electrode layer 140 may be formed using iridium, platinum, ruthenium, palladium, gold, iridium oxide, tin oxide, calcium ruthenium oxide (CaRuO₃; CRO), iridium ruthenium, indium tin oxide (ITO), a combination thereof, or the like. The lower electrode layer 140 may be formed by a sputtering process, a CVD process, an ALD process, a PLD process, or the like. According to at least one example embodiment, the lower electrode layer 140 may be formed by a sputtering process using iridium. The lower electrode layer 140 may be formed to have a thickness of about 200 Å.

Referring to FIG. 9, a first crystalline diffusion barrier layer 150 may be formed on the lower electrode layer 140. The first crystalline diffusion barrier layer 150 may be formed using a metal oxide such as strontium ruthenium oxide (SrRuO₃; SRO), strontium titanium oxide (SrTiO₃; STO), lanthanum nickel oxide (LnNiO₃; LNO), calcium ruthenium oxide (CaRuO₃; CRO), a combination thereof, or the like. The first crystalline diffusion barrier layer 150 may be formed by a sputtering process, a CVD process, an ALD process, a PLD process, or the like.

According to at least one example embodiment, the first crystalline diffusion barrier layer 150 may be formed by a sputtering process using strontium ruthenium oxide. The sputtering process may be performed at a relatively high temperature of between about 450° C. and about 550° C., inclusive; under a pressure of between about 5.8 mTorr and about 6.2 mTorr, inclusive; and at a relatively low power of between about 200 W and about 700 W, inclusive (e.g., at a relatively low power of about 400 W). When the sputtering process is performed at a relatively high power of more than about 1 kW, a SRO layer may have a relatively poor morphology, so that the sputtering process may be performed at the relatively low power.

In the sputtering process, a reaction gas may be argon gas, oxygen gas, or a mixed gas including argon gas and oxygen gas. The argon gas may be provided at a flow rate of between about 45 sccm and about 85 sccm, inclusive. The oxygen gas may be provided at a flow rate of between about 5 sccm and about 30 sccm, inclusive, (e.g., at a flow rate of about 10 sccm). When a mixed gas is used, a flow rate ratio between the argon gas and the oxygen gas may be in a range of between about 1.0:0.1 and about 1.0:0.7, inclusive. When the oxygen gas is provided at a higher flow rate, a ferroelectric layer 160 (see FIG. 10) may have a smaller grain size so that the value of the remaining polarization (2Pr) may be reduced.

Argon gas may also be provided at a rear surface of the substrate 100 at a flow rate of about 15 sccm, so that the strontium ruthenium oxide layer has a sufficient distribution (e.g., a relatively good distribution).

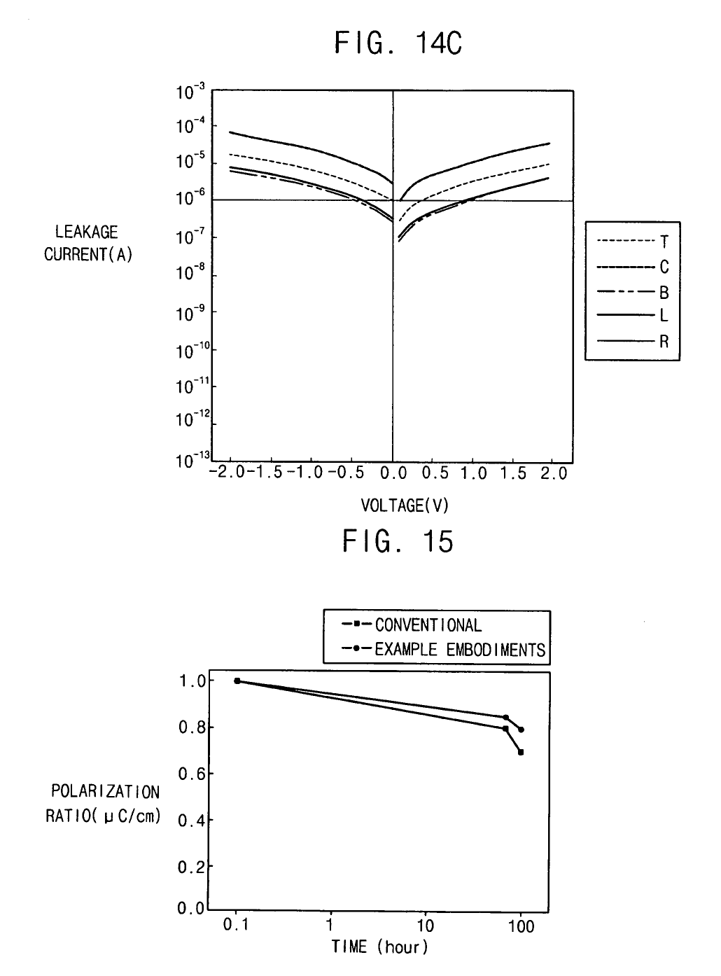

The strontium ruthenium oxide layer may be formed to have a thickness of between about 5 Å and about 45 Å, inclusive (e.g., a thickness of about 20 Å). The strontium ruthenium oxide layer may be deposited at a speed of less than about 2 Å/min. When a strontium ruthenium oxide layer has a thickness of greater than or equal to about 50 Å, a FRAM device including the ferroelectric capacitor may have a relatively low degree of integration, and the height difference between a maximal point and a minimal point of a top surface of the ferroelectric layer 160 (or a peak-to-valley (P-V) value) may increase, thereby generating a relatively large leakage current. The relationships between the thickness of the strontium ruthenium oxide layer and the leakage current are shown in FIGS. 14A, 14B, and 14C.

FIGS. 14A to 14C are graphs illustrating the relationships between the thickness of the SRO layer and the leakage current in accordance with example embodiments, which are graphs at locations (top portion: T, central portion: C, bottom portion: B, left portion: L, and right portion: R) of the substrate 100 when the thicknesses of the strontium ruthenium oxide layer are about 10 Å (FIG. 14A), about 20 Å (FIG. 14B) and about 50 Å (FIG. 14C), respectively.

Referring to FIGS. 14A to 14C, when the strontium ruthenium oxide layer has a thickness of more than about 50 Å, the leakage current is more than about 10⁻⁶ A. Accordingly, the thicker strontium ruthenium oxide layer has a leakage current larger than that of a strontium ruthenium oxide layer having a smaller thickness.

The first crystalline diffusion barrier layer 150 may suppress and/or prevent lead of the ferroelectric layer 160 or oxygen generated during formation of the ferroelectric layer 160 from diffusing into the insulating structure 110 or the plug 120, so that degeneration and/or deterioration of the insulating structure 110 and/or the plug 120 may be suppressed and/or prevented. Additionally, the first crystalline diffusion barrier layer 150 may mitigate fatigue of the ferroelectric layer 160.

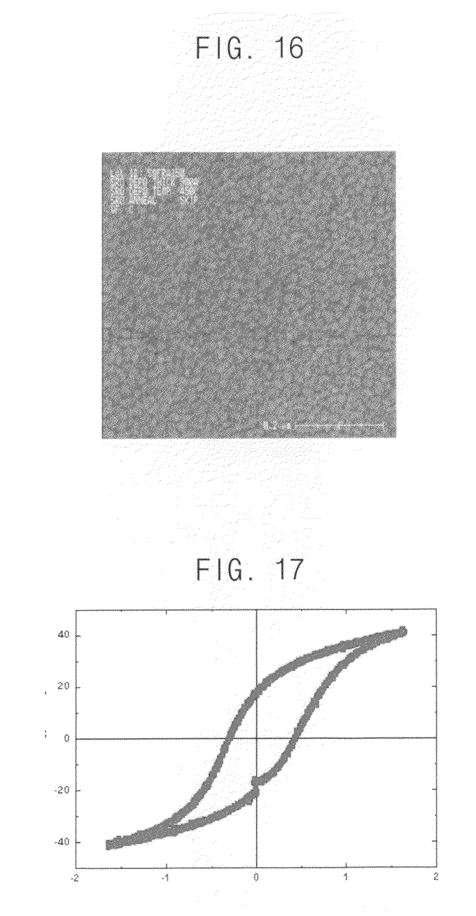

Conventionally, a crystalline strontium ruthenium oxide layer may be formed by depositing materials in an amorphous state (amorphous deposition) and annealing the materials, which may result in generation of the above-described defects in the crystalline strontium ruthenium oxide layer. According to example embodiments, however, a crystalline strontium ruthenium oxide layer may be formed at a relatively high temperature without depositing materials in an amorphous state and/or annealing, thereby suppressing and/or preventing generation of defects and/or enhancing electrical characteristics of the strontium ruthenium oxide layer. The enhanced electrical characteristics of the ferroelectric capacitor in accordance with at least some example embodiments are shown in FIGS. 15 to 18.

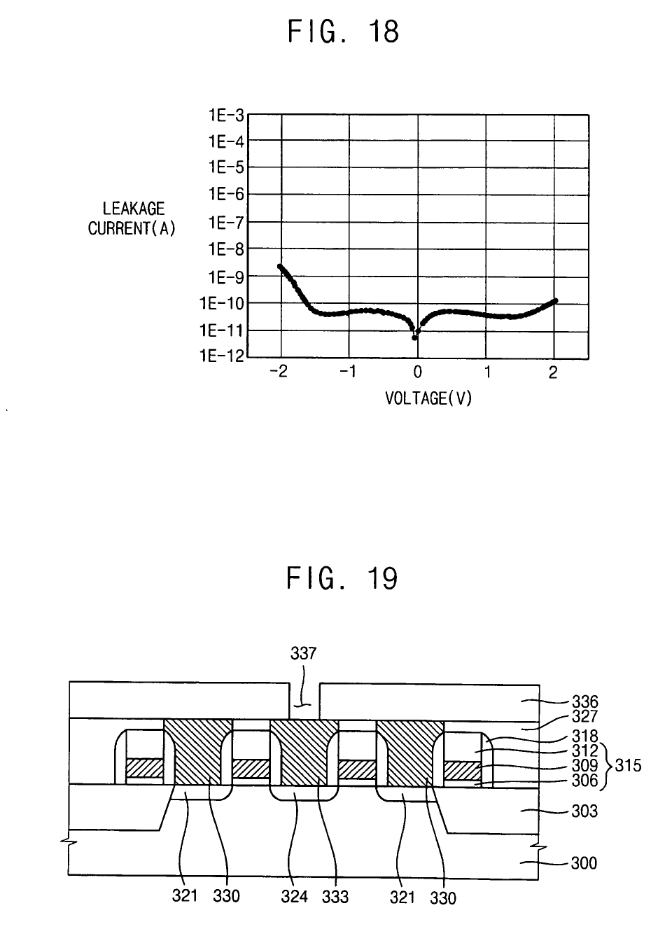

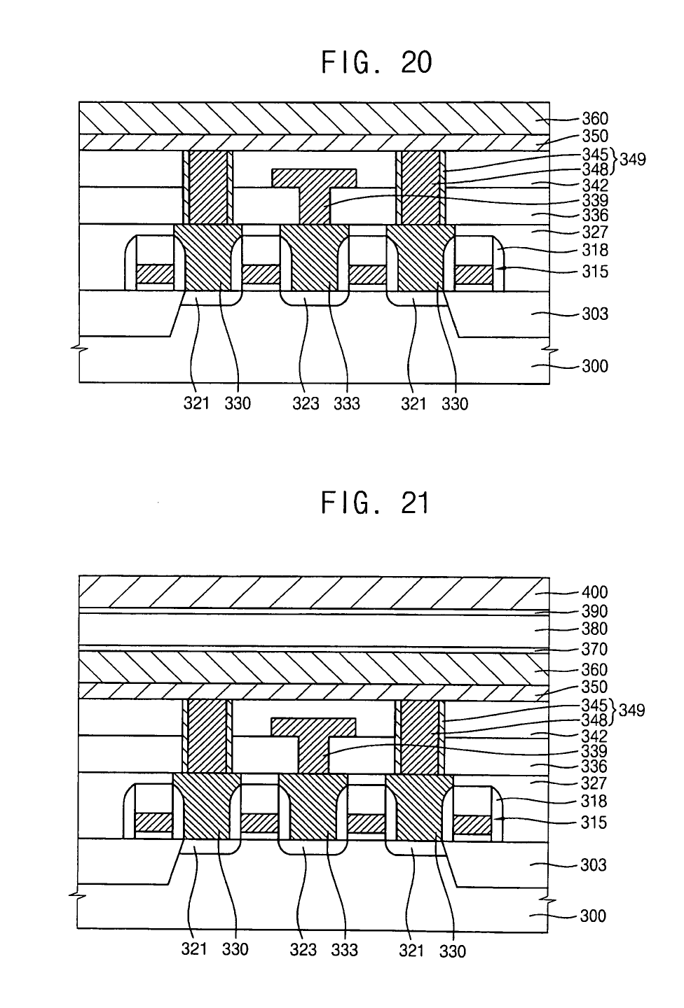

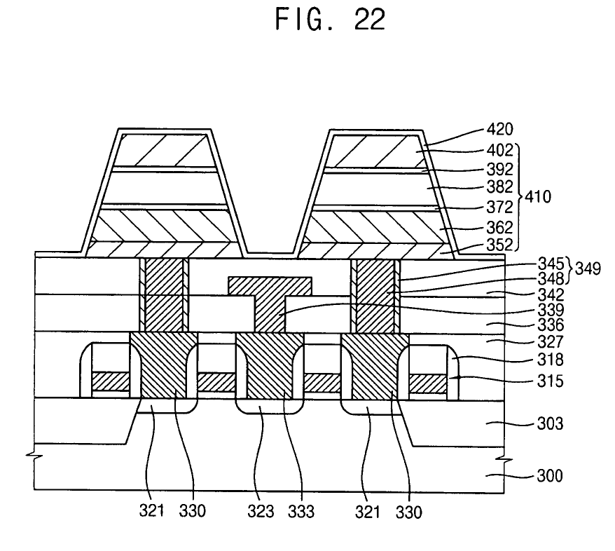

FIG. 15 is a graph illustrating a polarization ratio of the ferroelectric capacitor in accordance with example embodiments with respect to time. FIG. 16 is a scanning electron microscope (SEM) picture of a crystalline strontium ruthenium oxide layer included in the ferroelectric capacitor in accordance with example embodiments. FIG. 17 is a P-V hysteresis loop of the ferroelectric capacitor in accordance with example embodiments. FIG. 18 is a graph illustrating a leakage current of the ferroelectric capacitor in accordance with example embodiments. In obtaining the graphs shown in FIGS. 15 to 18, the strontium ruthenium oxide layer was deposited at a temperature of about 500° C., and a successive heat treatment was performed on the SRO layer at a temperature of about 457° C. A PZT layer serving as a ferroelectric layer was formed to have a thickness of about 60 nm. The flow rate of lead source gas was about 87 sccm.

As shown in FIG. 15, the reduction amount of the polarization ratio with respect to elapsed time for the ferroelectric capacitor is lower than that of the conventional ferroelectric capacitor. Accordingly, the ferroelectric layer according to example embodiments has improved data retention characteristics relative to the conventional art.

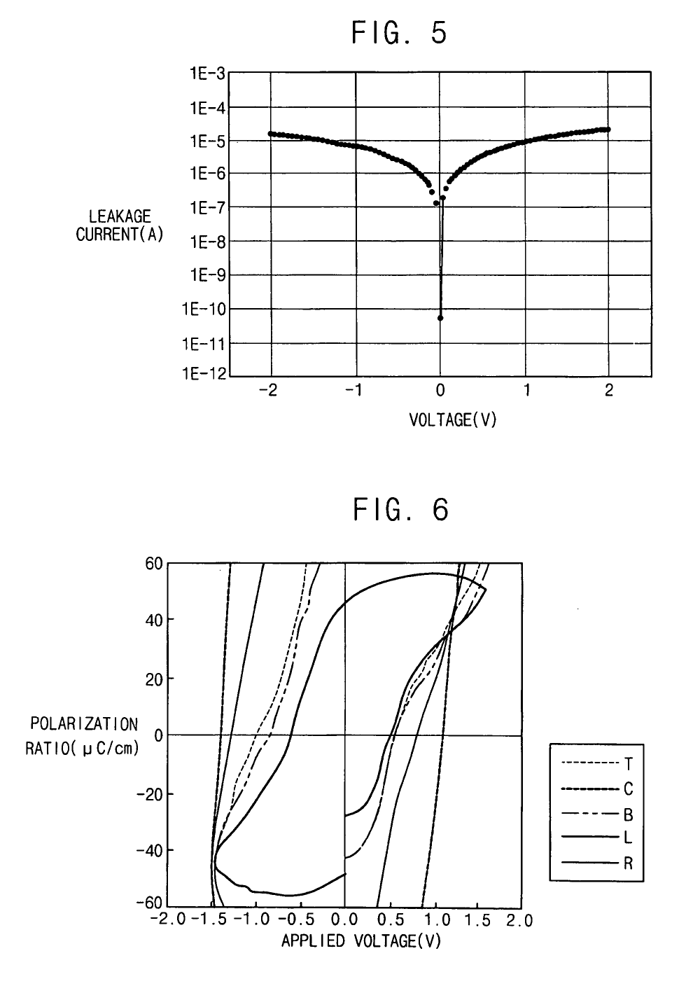

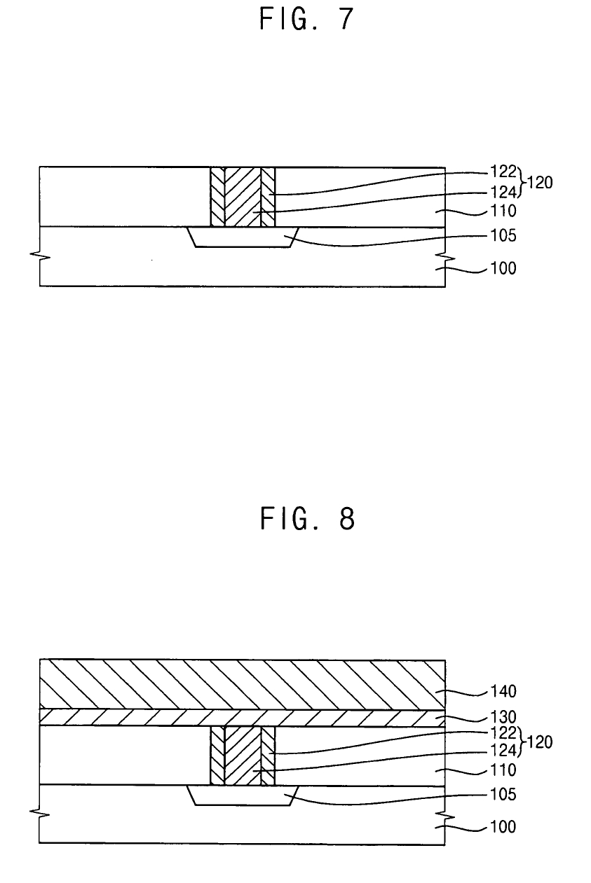

Referring to FIG. 16, when compared to FIGS. 3 and 4, the crystalline strontium ruthenium oxide layer according to example embodiments has fewer defects generated due to the volatilization of ruthenium tetraoxide (RuO₄) and the extraction of ruthenium dioxide (RuO₂).

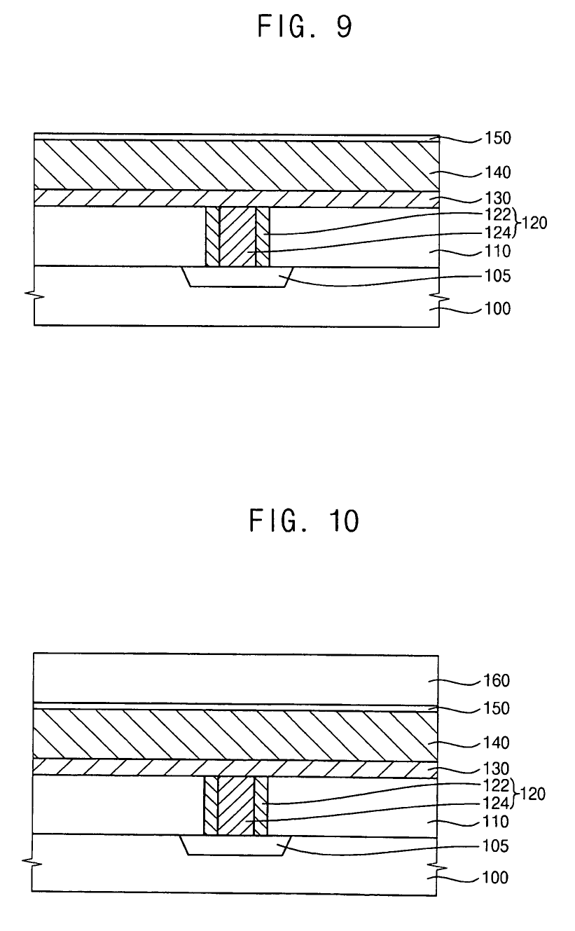

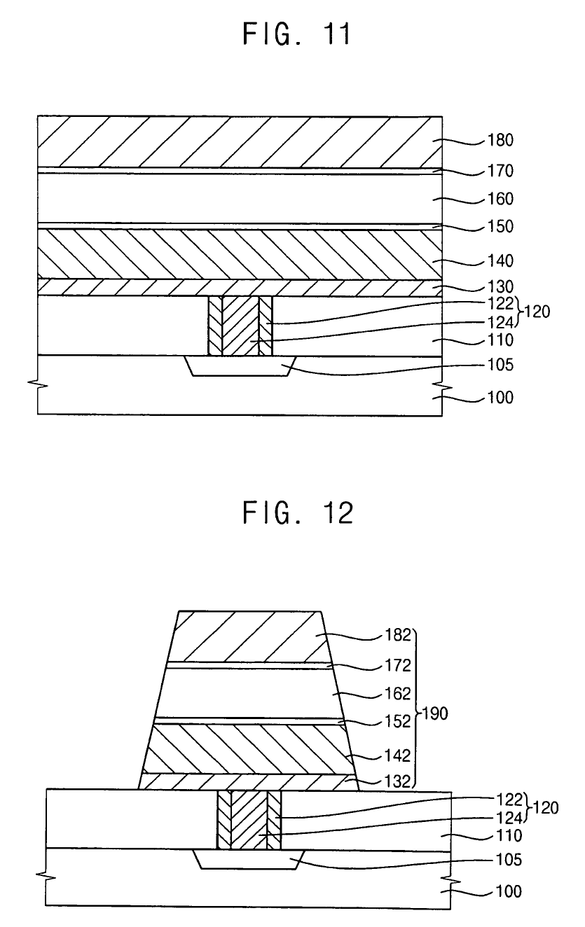

Referring to FIGS. 17 and 18, when compared to FIGS. 5 and 6, respectively, ferroelectric capacitors according to example embodiments have better P-V hysteresis loop and lower leakage current relative to the conventional art.

Referring back to FIG. 9, a heat treatment process may be performed to increase the density of the crystalline strontium ruthenium oxide layer 150. The heat treatment process may be performed at a temperature of between about 450° C. and about 600° C., inclusive (e.g., at a temperature of about 475° C.).

Referring to FIG. 10, the ferroelectric layer 160 may be formed on the first crystalline diffusion barrier layer 150.

The ferroelectric layer 160 may be formed using a ferroelectric material such as PZT, SBT, BLT, PLZT, BST, a combination thereof, or the like, or a ferroelectric material such as PZT, SBT, BLT, PLZT, BST, a combination thereof, or the like, doped with impurities such as calcium (Ca), lanthanum (La), manganese (Mn), bismuth (Bi), or the like. Alternatively, the ferroelectric layer 160 may be formed using a metal oxide such as titanium oxide (TiO₂), tantalum oxide (TaO₂), aluminum oxide (Al₂O₃), zinc oxide (ZnO₂), hafnium oxide (HfO₂), a combination thereof, or the like. The ferroelectric layer 160 may be formed by a metal organic chemical vapor deposition (MOCVD) process, a CVD process, an ALD process, or the like. According to at least one example embodiment, the ferroelectric layer 160 may be formed on the first crystalline diffusion barrier layer 150 by a MOCVD process using PZT. The formation of the ferroelectric layer 160 according to at least one example embodiment may be performed as follows.

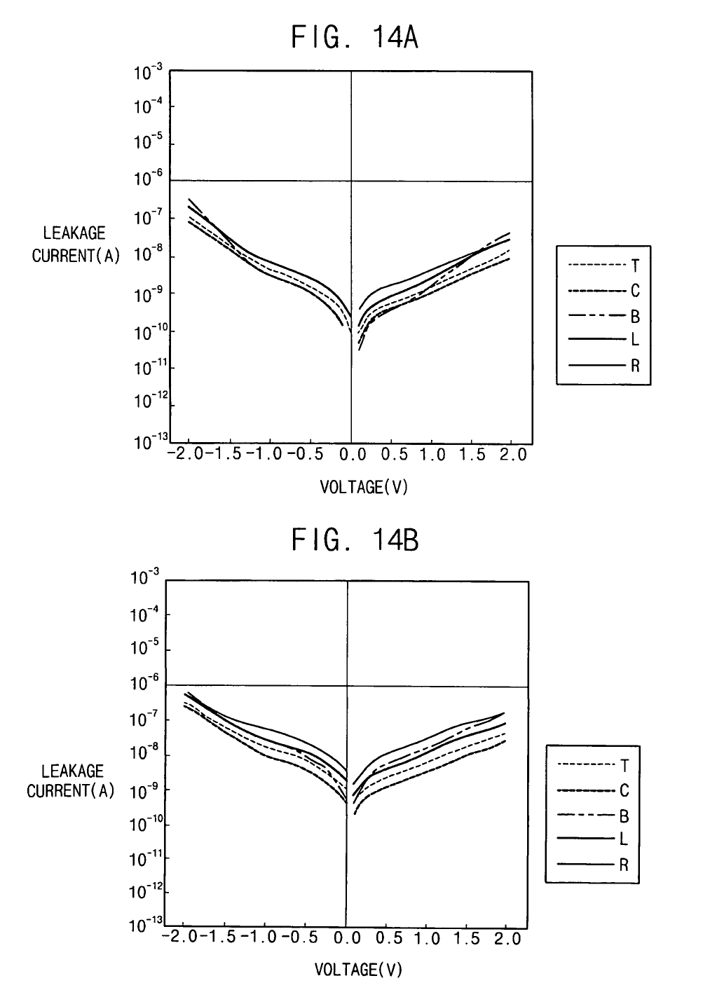

FIG. 13 is a cross-sectional view illustrating a MOCVD apparatus for forming a ferroelectric layer in accordance with example embodiments.

Referring to FIGS. 10 and 13, the substrate 100 having the above-described layers thereon may be loaded onto a susceptor (or platform) 220 in a process chamber 210 of the MOCVD apparatus. When forming the ferroelectric layer 160 on the first crystalline diffusion barrier layer 150 of the substrate 100, the substrate 100 may be maintained at a temperature of between about 550° C. and about 690° C., inclusive (e.g., at a temperature of about 620° C.). The process chamber 210 may be maintained at a pressure of between about 0.5 Torr and about 1.5 Torr, inclusive (e.g., at a pressure of about 1 Torr).

A shower head 230 having a first sprayer 232 and a second sprayer 234 may be located at an upper portion of the process chamber 210 above the susceptor 220. The first sprayer 232 may include a plurality of first nozzles 233, and a second sprayer 234 includes a plurality of second nozzles 235 arranged alternately with the first nozzles 233. In at least one example embodiment, the shower head 230 may be arranged about 10 mm from (above) the substrate 100, which is arranged on the susceptor 220. As the distance between the shower head 230 and the substrate 100 increases, data retention of the ferroelectric layer 160 formed in the process chamber 210 may improve.

A metal organic precursor for forming the ferroelectric layer 160 may be supplied to a vaporizer 246 from a metal organic precursor source 242. The vaporizer 246 may heat the metal organic precursor to a given temperature. A carrier gas may be supplied to the vaporizer 246 from a carrier gas source 244. The vaporizer 246 may heat the carrier gas to a given temperature together with the metal organic precursor. The metal organic precursor may include at least a first compound, a second compound and a third compound. The first compound may include, for example, lead. The second compound may include, for example, zirconium. The third compound may include, for example, titanium. The carrier gas may include an inactive gas such as nitrogen gas, helium gas, argon gas, etc. The heated metal organic precursor and the carrier gas in the vaporizer 246 may be supplied to the chamber 210 and provided onto the substrate 100 via the first nozzles 233 of the first sprayer 232.

Still referring to FIG. 13, an oxidizer may be supplied to a heater 256 from an oxidizer source 252. The heater 256 may heat the supplied oxidizer to a given temperature. The heated oxidizer may be supplied to the chamber 210 and provided onto the substrate 100 via the second nozzles 235 of the second sprayer 234. The heated oxidizer and the heated metal organic precursor may have the same or substantially the same temperature. The oxidizer may include oxygen (O₂), ozone (O₃), nitrogen dioxide (NO₂), nitrous oxide (N₂O), or the like.

The metal organic precursor reacts with the oxidizer to form the ferroelectric layer 160. When this reaction occurs, flow rates of the metal organic precursor and the oxidizer may be controlled by opening/closing first and second valves 248 and 258.

In at least one example embodiment, the ferroelectric layer 160 may have a chemical formula of Pb(Zr₁₋ₓ, Tiₓ)O₃, wherein 0.65≦x≦0.80 (e.g., x=0.70). The PZT layer may have a grain size of between about 100 nm and about 150 nm, inclusive.

As described above, forming a ferroelectric layer at a relatively high temperature may result in the diffusion of lead and/or oxygen into other layers. However, according to example embodiments, the first crystalline diffusion barrier layer 150 may suppress and/or prevent diffusion of lead and/or oxygen into the insulating structure 110 and/or the plug 120.

After forming the ferroelectric layer 160, a polishing process and/or a cleaning process may be further performed to reduce the roughness of the ferroelectric layer 160.

Referring to FIG. 11, a second crystalline diffusion barrier layer 170 and an upper electrode layer 180 may be formed on the ferroelectric layer 160. The second crystalline diffusion barrier layer 170 and the upper electrode layer 180 may be formed by the same or substantially the same processes for forming the first crystalline diffusion barrier layer 150 and the lower electrode layer 140, respectively. Thus, detailed descriptions are omitted here.

Referring to FIG. 12, after forming a second photoresist pattern (not illustrated) on the upper electrode layer 180, the upper electrode layer 180, the second crystalline diffusion barrier layer 170, the ferroelectric layer 160, the first crystalline diffusion barrier layer 150, the lower electrode layer 140 and the adhesion layer 130 may be patterned using the second photoresist pattern as an etching mask, thereby forming a ferroelectric capacitor 190 including an upper electrode 182, a second crystalline diffusion barrier layer pattern 172, a ferroelectric layer pattern 162, a first crystalline diffusion barrier layer pattern 152, a lower electrode 142 and an adhesion layer pattern 132. The ferroelectric capacitor 190 may have a sidewall inclined at an angle of between about 50° and about 80°, inclusive, relative to the upper surface of the substrate 100 by the etching process.

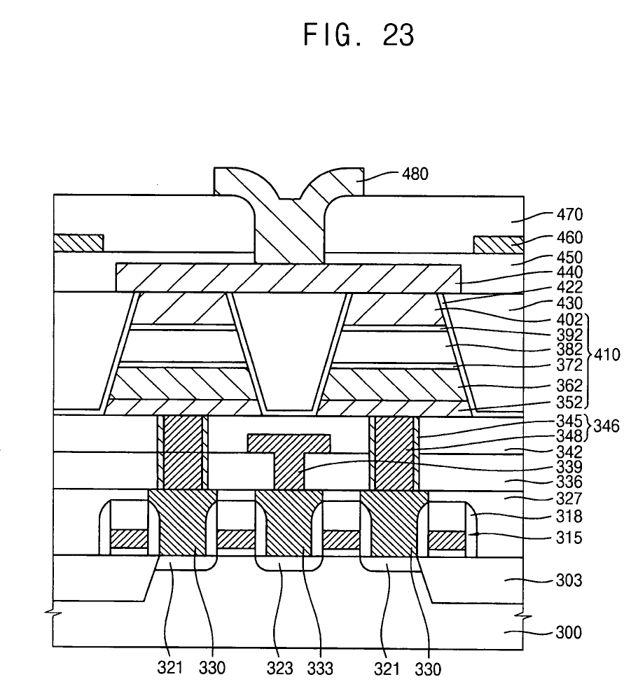

FIGS. 19 to 23 are cross-sectional views illustrating a method of manufacturing a semiconductor device including the method of forming the ferroelectric capacitor according to example embodiments.

Referring to FIG. 19, an isolation layer 303 may be formed on (or within a portion of) the substrate 300 to define an active region and a field region in the substrate 300. The isolation layer 303 may be formed by an isolation process such as a shallow trench isolation (STI) process or the like. A gate insulation layer may be formed on the substrate 300. The gate insulation layer may be a gate oxide layer formed by a thermal oxidation process or a CVD process. In an example embodiment, the gate insulation layer may be formed on (e.g., only on) the active region of the substrate 300. A first conductive layer and a first mask layer may be formed on the gate insulation layer. In one example, the first conductive layer may be formed using doped polysilicon. Alternatively, the first conductive layer may be formed using doped polysilicon and a metal silicide, so that the first conductive layer may have a poly-side structure.

The first mask layer may be formed using a material having an etching selectivity with respect to a first insulating interlayer 327. For example, when the first insulating interlayer 327 includes an oxide, the first mask layer may be formed using a nitride such as silicon nitride. After forming a first photoresist pattern (not shown) on the first mask layer, the first mask layer, the first conductive layer and the gate insulation layer may be patterned using the first photoresist pattern as an etching mask, thereby forming a gate structure 315 including a gate insulation layer pattern 306, a gate conductive layer pattern 309 and a gate mask pattern 312.

A first insulation layer may be formed using a nitride such as silicon nitride on the substrate 300 on which the gate structure 315 is formed. The first insulation layer may be anisotropically etched to form a gate spacer 318 on a sidewall of the gate structure 315. Impurities may be implanted onto (or into) an upper portion of the substrate 300 exposed by the gate structure 315 and the gate spacer 318 by an ion implantation process, and a heat treatment process may be performed on the substrate 300, thereby forming a first contact region 321 and a second contact region 324 in the substrate 300. The first and second contact regions 321 and 324 may be divided into a capacitor contact region and a bit line contact region. A first plug 330 for a ferroelectric capacitor 410 (see FIG. 22) may contact the capacitor contact region, and a second plug 333 for a bit line 339 (see FIG. 20) may contact the bitline contact region. In one example, the first contact region 321 may serve as the capacitor contact region electrically connected to the first plug 330, and the second contact region 324 may serve as the bit line contact region electrically connected to the second plug 333. Thus, a plurality of transistors, each of which includes the gate structure 315, the gate spacer 318 and the contact regions 321 and 324 may be formed on the substrate 300.

A first insulating interlayer 327 may be formed on the substrate 300 using an oxide. The first insulating interlayer 327 may cover the gate structure 315. The first insulating interlayer 327 may be formed using, for example, BPSG, PSG, SOG, PE-TEOS, USG, HDP-CVD oxide, a combination thereof, or the like by a CVD process, a PECVD process, a HDP-CVD process, an ALD process, or the like. An upper portion of the first insulating interlayer 327 may be removed by a CMP process and/or an etch-back process to planarize a top surface of the first insulating interlayer 327.

After forming a second photoresist pattern (not shown) on the planarized first insulating interlayer 327, the first insulating interlayer 327 may be partially removed by an anisotropic etching process using the second photoresist pattern as an etching mask, thereby forming a plurality of holes (not illustrated) exposing the first and second contact regions 321 and 324. The first holes may be self-aligned with respective gate structures 315, and may expose the first and second contact regions 321 and 324. Some of the first holes expose the capacitor contact region (e.g., the first contact region 321), whereas others of the first holes expose the bit line contact region (e.g., the second contact region 324). After removing the second photoresist pattern by an ashing process and/or a stripping process, a second conductive layer may be formed on the first insulating interlayer 327 to fill the first holes. The second conductive layer may be formed using relatively highly doped polysilicon, a metal, a conductive metal nitride or the like. The second conductive layer may be partially removed until the planarized top surface of the first insulating interlayer 327 is exposed, thereby forming the first and second plugs 330 and 333 filling the first holes, each of which is a self-aligned contact (SAC). The first plug 330 may be formed on the capacitor contact region (e.g., the first contact region 321), whereas the second plug 333 may be formed on the bit line contact region (e.g., the second contact region 324). Thus, the first plug 330 may contact the capacitor contact region, whereas the second plug 333 may contact the bit line contact region.

A second insulating interlayer 336 may be formed on the first insulating interlayer 327 having the first and second plugs 330 and 333 formed there through. The second insulating interlayer 336 may electrically insulate the first plug 330 from the bit line 339. The second insulating interlayer 336 may be formed using, for example, BPSG, PSG, SOG, PE-TEOS, USG, HDP-CVD oxide, a combination thereof, or the like by a CVD process, a PECVD process, a HDP-CVD process, an ALD process, or the like. An upper portion of the second insulating interlayer 336 may be partially removed to planarize a top surface of the second insulating interlayer 336. After forming a third photoresist pattern (not illustrated) on the planarized second insulating interlayer 336, the second insulating interlayer 336 may be partially removed using the third photoresist pattern as an etching mask, thereby forming a second hole 337 exposing the second plug 333. The second hole 337 may serve as a bit line contact hole for electrically connecting the second plug 333 and the bit line 339.

Referring to FIG. 20, after removing the third photoresist pattern, a third conductive layer may be formed on the second insulating interlayer 336 to fill the second hole. After forming a fourth photoresist pattern (not illustrated) on the third conductive layer, the third conductive layer may be partially removed using the fourth photoresist pattern as an etching mask, thereby forming the bit line 339 on the second insulating interlayer 336 filling the second hole 337. The bit line 339 may have a multi-layered structure in which a first layer including a metal or a metal compound and a second layer including a metal may be formed. The first layer may include, for example, titanium and/or titanium nitride. The second layer may include, for example, tungsten. A third insulating interlayer 342 may be formed on the second insulating interlayer 336 to cover the bit line 339 using, for example, BPSG, PSG, SOG, PE-TEOS, USG, HDP-CVD oxide, a combination thereof, or the like by a CVD process, a PECVD process, a HDP-CVD process, an ALD process, or the like. An upper portion of the third insulating interlayer 342 may be removed to planarize a top surface of the third insulating interlayer 342.

After forming a fifth photoresist pattern (not illustrated) on the planarized third insulating interlayer 342, the third insulating interlayer 342 and the second insulating interlayer 336 may be partially removed using the fifth photoresist pattern as an etching mask, thereby forming a plurality of third holes (not illustrated) exposing the first plugs 330. Each of the third holes may serve as a capacitor hole. A fourth conductive layer and a fifth conductive layer may be formed on the third insulating interlayer 342 to fill the third holes, and upper portions of the fourth and fifth conductive layers may be removed until the planarized along with the top surface of the third insulating interlayer 342, thereby forming third plugs 349 filling the third holes. Each of the third plugs 349 may include a first conductive layer pattern 345 and a second conductive layer pattern 348. The fifth conductive layer may be formed using doped polysilicon or a metal. The fourth conductive layer may be formed using a conductive metal nitride. An adhesion layer 350 and a lower electrode layer 360 may be formed successively. The lower electrode layer 360 may be electrically connected to the first contact region 321 via the third plug 349 and the first plug 330.

The adhesion layer 350 and the lower electrode layer 360 may be formed on the third insulating interlayer 342 and the third plug 349 using the same or substantially the same processes described above with reference to FIG. 8.

Referring to FIG. 21, a first crystalline diffusion barrier layer 370, a ferroelectric layer 380, a second crystalline diffusion barrier layer 390 and an upper electrode layer 400 may be formed on the lower electrode layer 360 using the same or substantially the same processes described above with reference to FIGS. 9 to 11.

Referring to FIG. 22, a ferroelectric capacitor 410 including an upper electrode 402, a second crystalline diffusion barrier layer 392, a ferroelectric layer pattern 382, a first crystalline diffusion barrier layer 372, a lower electrode 362 and an adhesion layer pattern 382 may be formed using the same or substantially the same processes illustrated with reference to FIG. 12. A barrier layer 420 may be formed on the third insulating interlayer 342 to cover the ferroelectric capacitor 410. The barrier layer 420 may be formed using a metal oxide, a metal nitride or the like by a CVD process, an ALD process, a sputtering process or the like. The barrier layer 420 may suppress and/or prevent hydrogen from diffusing into the ferroelectric layer pattern 382, thereby suppressing deterioration of characteristics of the ferroelectric layer pattern 382. In some cases, the barrier layer 420 may be omitted.

Referring to FIG. 23, a fourth insulating interlayer 430 may be formed on the barrier layer 420. The fourth insulating interlayer 430 may be formed using BPSG, PSG, SOG, PE-TEOS, USG, HDP-CVD oxide or the like. The fourth insulating interlayer 430 and the barrier layer 420 may be partially removed until the upper electrode 402 is exposed to transform the barrier layer 420 into a barrier layer pattern 422. A sixth conductive layer may be formed on the fourth insulating interlayer 430 and the exposed upper electrode 402. The sixth conductive layer may be formed using a metal, a conductive metal oxide, a conductive metal nitride, a combination thereof, or the like by a CVD process, a sputtering process, an ALD process, or the like. After forming a sixth photoresist pattern (not shown) on the sixth conductive layer, the sixth conductive layer may be patterned using the sixth photoresist pattern as an etching mask, thereby forming a plate line 440 electrically connected to the upper electrode 402. The plate line 402 may contact each of (make common contact with) the upper electrodes 402 adjacent to each other. A fifth insulating interlayer 450 may be formed on the fourth insulating interlayer 430 to cover the plate line 440. The fifth insulating interlayer 450 may be formed using BPSG, PSG, SOG, PE-TEOS, USG, HDP-CVD oxide, a combination thereof, or the like.

A seventh conductive layer may be formed on the fifth insulating interlayer 450 using a metal, a conductive metal nitride or the like. After forming a seventh photoresist pattern (not illustrated) on the seventh conductive layer, the seventh conductive layer may be patterned using the seventh photoresist pattern as an etching mask, thereby forming a first upper wiring 460 on the fifth insulating interlayer 450. In at least one example embodiment, the first upper wiring 460 may serve as a word line. A sixth insulating interlayer 470 may be formed on the fifth insulating interlayer 450 to cover the first upper wiring 460. After forming an eighth photoresist pattern (not illustrated) on the sixth insulating interlayer 470, the sixth and fifth insulating interlayers 470 and 450 may be partially removed using the eighth photoresist pattern as an etching mask, thereby forming a fourth hole (not shown) exposing the plate line 440 there through. An eighth conductive layer may be formed on the sixth insulating interlayer 470 to fill the fourth hole. After forming a ninth photoresist pattern (not illustrated) on the eighth conductive layer, the eighth conductive layer may be partially removed using the ninth photoresist pattern as an etching mask, thereby forming a second upper wiring 480. Thus, the semiconductor device including the ferroelectric capacitors may be manufactured.

According to at least some example embodiments, a crystalline diffusion barrier layer may be formed beneath and/or on a ferroelectric layer to suppress and/or prevent diffusion of components of the ferroelectric layer into peripheral layers (e.g., a lower electrode layer, an upper electrode layer, a plug, etc.), and/or reduce fatigue/deterioration of the ferroelectric layer. The crystalline diffusion barrier layer may be formed at a relatively high temperature by a sputtering process, thereby suppressing formation of defects generated in the crystalline diffusion barrier layer during annealing an amorphous layer after depositing the amorphous layer at a relatively low temperature. Thus, a ferroelectric capacitor including the diffusion barrier layer may have improved P-V hysteresis characteristics and/or reduced leakage current characteristics. Additionally, a semiconductor device including the ferroelectric capacitor may have enhanced reliability.

The foregoing is illustrative of example embodiments, but is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of forming a ferroelectric capacitor, comprising:
forming a lower electrode layer on a substrate;
forming a first crystalline diffusion barrier layer on the lower electrode layer, the first crystalline diffusion barrier layer being for at least one of preventing diffusion of a component of a ferroelectric layer into the lower electrode layer and for mitigating fatigue of the ferroelectric layer;
forming the ferroelectric layer on the first crystalline diffusion barrier layer; and
forming an upper electrode layer on the ferroelectric layer.

2. The method of claim 1, wherein the first crystalline diffusion barrier layer is formed using strontium ruthenium oxide (SRO).

3. The method of claim 2, wherein the first crystalline diffusion barrier layer is formed at a temperature of about 450° C. to about 550° C., inclusive, by a sputtering process.

4. The method of claim 3, wherein the sputtering process is performed under a pressure of between about 5.8 mTorr and about 6.2 mTorr, inclusive, at a power of between about 200 W and about 700 W, inclusive.

5. The method of claim 3, wherein after performing the sputtering process, the method further comprises:
performing a heat treatment process on the first crystalline diffusion barrier layer at a temperature of between about 450° C. and about 600° C., inclusive.

6. The method of claim 3, wherein the sputtering process is performed using argon gas or a mixed gas including argon gas and oxygen gas.

7. The method of claim 6, wherein a flow rate ratio between the argon gas and the oxygen gas is in a range of between about 1.0:0.1 and about 1.0:0.7, inclusive.

8. The method of claim 6, wherein the argon gas is provided onto a rear surface of the substrate at a flow rate of about 15 sccm.

9. The method of claim 2, wherein the first crystalline diffusion barrier layer is formed to have a thickness of between about 5 Å and about 45 Å, inclusive.

10. The method of claim 1, further comprising:
forming a second crystalline diffusion barrier layer between the ferroelectric layer and the upper electrode.

11. The method of claim 10, wherein the second crystalline diffusion barrier layer is formed at a temperature of between about 450° C. and about 550° C., inclusive, by a sputtering process.

12. The method of claim 1, wherein the ferroelectric layer is formed using one selected from the group consisting of lead zirconate titanate [Pb(Zr, Ti)O₃; PZT], strontium bismuth tantalate (SrBi₂Ta₂O₉; SBT), bismuth lanthanum titanate [(Bi, La)TiO₃; BLT], lead lanthanum zirconate litanate [(Pb, La)(Zr, Ti)O₃; PLZT] and barium strontium titanate [(Ba, Sr)TiO₃; BST].

13. The method of claim 12, wherein the ferroelectric layer is formed to have a thickness of between about 100 Å and about 800 Å, inclusive.

14. The method of claim 12, wherein the ferroelectric layer includes PZT having the formula of Pb(Zr₁₋ₓ, Tiₓ)O₃ in which 0.65≦x≦0.80.

15. The method of claim 1, wherein the ferroelectric layer is formed by a metal organic chemical vapor deposition (MOCVD) process, a chemical vapor deposition (CVD) process, or an atomic layer deposition (ALD) process.

16. The method of claim 15, wherein the ferroelectric layer is formed in a chamber of a MOCVD apparatus, the chamber including a shower head for spraying a gas, the shower head being separated from the substrate by about 10 mm.

17. The method of claim 1, wherein the lower electrode layer is formed using at least one selected from the group consisting of iridium, platinum, ruthenium, palladium, gold, iridium oxide, tin oxide, calcium ruthenium oxide (CRO), iridium ruthenium, and indium tin oxide (ITO).

18. The method of claim 1, wherein the upper electrode layer is formed using at least one selected from the group consisting of iridium, platinum, ruthenium, palladium, gold, iridium oxide, tin oxide, calcium ruthenium oxide (CaRuO₃; CRO), iridium ruthenium, and indium tin oxide (ITO).

19. The method of claim 1, wherein the first crystalline diffusion barrier layer is a first crystalline strontium ruthenium oxide (SRO) layer, the method further comprising:
forming a second crystalline strontium ruthenium oxide layer on the ferroelectric layer; and wherein
the upper electrode layer is formed on the second crystalline strontium ruthenium oxide layer.

20. The method of claim 19, wherein the first and second crystalline strontium ruthenium oxide layers are formed at a temperature of between about 450° C. and about 550° C., inclusive, by a sputtering process.

21. A method of manufacturing a semiconductor device, comprising:
forming a switching element on a substrate;
forming the ferroelectric capacitor as claimed in claim 1.

22. The method of claim 21, wherein the first crystalline diffusion barrier layer is formed using strontium ruthenium oxide (SRO).

23. The method of claim 22, wherein the first crystalline diffusion barrier layer is formed at a temperature of between about 450° C. and about 550° C. by a sputtering process.

24. The method of claim 23, wherein after performing the sputtering process, the method further comprises:
performing a heat treatment process on the first crystalline diffusion barrier layer at a temperature of between about 450° C. and about 600° C., inclusive.

25. The method of claim 21, wherein the first crystalline diffusion barrier layer is formed to have a thickness of between about 5 Å and about 45 Å, inclusive.

26. The method of claim 21, further comprising:
forming a second crystalline diffusion barrier layer on the ferroelectric layer; and wherein
the upper electrode is formed on the second crystalline diffusion barrier layer.

27. The method of claim 21, wherein the ferroelectric layer is formed using any one selected from the group consisting of lead zirconate titanate, strontium bismuth tantalate, bismuth lanthanum titanate, lanthanum doped lead zirconate titanate and barium strontium titanate.

28. The method of claim 1, wherein the first crystalline diffusion barrier layer is formed without amorphous deposition or annealing.

29. A method of forming a ferroelectric capacitor, comprising:
forming a lower electrode layer on a substrate;
forming a ferroelectric layer on the lower electrode;
forming a crystalline diffusion barrier layer on the ferroelectric layer, the crystalline diffusion barrier layer being for at least one of preventing diffusion of a component of a ferroelectric layer into the upper electrode layer and for mitigating fatigue of the ferroelectric layer, and
forming an upper electrode layer on the crystalline diffusion barrier layer.
